(19) United States
(12) Patent Application Publication
(10) Pub. No.: US 2025/0386559 A1
(43) Pub. Date: Dec. 18, 2025

(54) DIELECTRIC LINER PROTECTION TO PREVENT SHORTING TO GATE

(71) Applicant: INTERNATIONAL BUSINESS MACHINES CORPORATION, Armonk, NY (US)

(72) Inventors: Tsung-Sheng Kang, Albany, NY (US); Tao Li, Albany, NY (US); Ruilong Xie, Albany, NY (US); John Christopher Arnold, Albany, NY (US)

(21) Appl. No.: 18/747,123

(22) Filed: Jun. 18, 2024

(51) Int. Cl. H01L 29/06; H01L 29/08; H01L 29/66; H01L 29/786

(52) U.S. Cl. CPC H10D 62/115; H10D 30/025; H10D 30/6757; H10D 62/118; H10D 62/151; H10D 64/017

(57) ABSTRACT

A microelectronic structure, comprising a nanosheet field-effect-transistor (FET) is provided that includes a source/drain and a backside contact connected to a backside surface of the source/drain. The backside contact has a first section having a first width as measured perpendicular to a gate direction. The backside contact also has a second section having a second width as measured perpendicular to the gate direction. The first width is smaller than the second width. A vertical dielectric liner is provided that includes a plurality of vertical segments. Each of the vertical segments are located adjacent to a sidewall of a first section of the backside contact. A backside interlayer dielectric layer is located adjacent to the vertical dielectric liner. The backside contact is in contact with the backside interlayer dielectric layer between the two vertical segments of the plurality vertical segments of the dielectric liner.

### BACKGROUND

The present invention generally relates to the field of semiconductor technology, and more particularly to techniques for controlling a lateral etch during a processing stage.

Semiconductor or nanosheet technology have been evolving rapidly, especially relating to fabrication and design of transistors. Integrated circuitry (IC) continues to scale to smaller feature dimensions and higher transistor densities. This has led to increasingly densely packed semiconductor devices that utilize both front side and backside of the chip/circuit to provide electrical interconnections. In general, using backside interconnections have improved various aspects of semiconductor device configuration and performance.

### BRIEF SUMMARY

Additional aspects and/or advantages will be set forth in part in the description which follows and, in part, will be apparent from the description, or may be learned by practice of the invention.

A microelectronic structure and a method for fabricating the microelectronic structure is provided.

In an embodiment, the microelectronic structure and a related method to fabricate the structure comprises a nanosheet field-effect-transistor (FET) is provided that includes a source/drain and a backside contact connected to a backside surface of the source/drain. The backside contact has a first section having a first width as measured perpendicular to a gate direction. The backside contact also has a second section having a second width as measured perpendicular to the gate direction. The first width is smaller than the second width. A vertical dielectric liner is provided that includes a plurality of vertical segments. Each of the vertical segments of the vertical dielectric liner are located adjacent to a sidewall of a first section of the backside contact. A backside interlayer dielectric layer is located adjacent to the vertical dielectric liner. The backside contact is in contact with the backside interlayer dielectric layer between the two vertical segments of the plurality vertical segments of the dielectric liner.

In an alternate embodiment, the microelectronic structure comprises a nanosheet field-effect-transistor (FET) is provided that includes a source/drain and a backside contact connected to a backside surface of the source/drain. The backside contact has a first section having a first width as measured perpendicular to a gate direction. The backside contact also has a second section having a second width as measured perpendicular to the gate direction. The first width is smaller than the second width. A vertical dielectric liner is provided that includes a plurality of vertical segments. Each of the vertical segments of the vertical dielectric liner are located adjacent to a sidewall of a first section of the backside contact. A backside interlayer dielectric layer is located adjacent to the vertical dielectric liner. The backside contact is in contact with the backside interlayer dielectric layer between the two vertical segments of the plurality vertical segments of the dielectric liner. A liner is provided that is located around a shallow trench isolation layer. The backside contact is in contact with the liner between the two vertical segments of the plurality vertical segments of the dielectric liner.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a top-down illustration, showing multiple devices, in accordance with an embodiment.

FIGS. 2 provides a perspective across the X cross-section after some initial fabrication steps including patterning and layer formations according to an embodiment.

FIG. 3 illustrates cross section Y1 after the initial processing steps, in accordance with an embodiment of the present invention.

FIG. 4 illustrated cross section Y2 after the initial processing steps, according to an embodiment.

FIGS. 5 illustrates a processing stage after a placeholder formation and source/drain epi growth formation across an X cross-section, according to an embodiment.

FIGS. 6 illustrates a processing stage after a placeholder formation and source/drain epi growth formation across a Y1 cross-section, according to an embodiment.

FIGS. 7 illustrates a processing stage after a placeholder formation and source/drain epi growth formation across a Y2 cross-section, according to an embodiment.

FIG. 8 illustrates a processing stage after the addition of a carrier wafer and a back of line (BEOL) layer formation across an X cross-section, according to an embodiment.

FIG. 9 illustrates a processing stage after the of a carrier wafer and a back of line (BEOL) layer formation across a Y1 cross-section, according to an embodiment

FIG. 10 illustrates a processing stage after ng addition of a carrier wafer and a back of line (BEOL) layer formation across a Y2 cross-section, according to an embodiment.

FIG. 11 illustrates a processing stage after a backside processing is performed across an X cross-section, according to an embodiment.

FIG. 12 illustrates a processing stage after backside processing is performed across a Y1 cross-section, according to an embodiment.

FIG. 13 illustrates a processing stage after backside processing is performed across a Y2 cross-section, according to an embodiment.

FIG. 14 illustrates a processing stage after a backside etching process is performed across an X cross-section, according to an embodiment.

FIG. 15 illustrates a processing stage after a backside etching process is performed across a Y1 cross-section, according to an embodiment.

FIG. 16 illustrates a processing stage after a backside etching process is performed across a Y2 cross-section, according to an embodiment.

FIG. 17 illustrates a processing stage after removal of the placeholder across an X cross-section, according to an embodiment.

FIG. 18 illustrates a processing stage after removal of the placeholder across a Y1 cross-section, according to an embodiment.

FIG. 19 illustrates a processing stage after removal of the placeholder across a Y2 cross-section, according to an embodiment.

FIG. 20 illustrates a processing stage after removal of some of the source/drain area across an X cross-section, according to an embodiment.

FIG. 21 illustrates a processing stage after removal of some of the source/drain across a Y1 cross-section, according to an embodiment.

FIG. 22 illustrates a processing stage after removal of some of the source/drain across a Y2 cross-section, according to an embodiment.

FIG. 23 illustrates a processing stage after performance of a pre-silicide cleaning step, causing a gauging in some of areas without a liner protection, across an X cross-section, according to an embodiment.

FIG. 24 illustrates a processing stage after performance of a pre-silicide cleaning step, causing a gauging in some of areas without a liner protection, across a Y1 cross-section, according to an embodiment.

FIG. 25 illustrates a processing stage after performance of a pre-silicide cleaning step, causing a gauging in some of areas without a liner protection, across a Y2 cross-section, according to an embodiment.

FIG. 26 illustrates a processing stage after a metallization step and formation of backside contacts, across an X cross-section, according to an embodiment.

FIG. 27 illustrates a processing stage after a metallization step and formation of backside contacts, across a Y1 cross-section, according to an embodiment.

FIG. 28 illustrates a processing stage after a metallization step and formation of backside contacts, across a Y2 cross-section, according to an embodiment.

FIG. 29 illustrates a processing stage after formation of a field-effect-transistor (FET), across an X cross-section, according to an embodiment.

FIG. 30 illustrates a processing stage after formation of a filed-effect-transistor (FET), across a Y1 cross-section, according to an embodiment.

FIG. 31 illustrates a processing stage after formation of a filed-effect-transistor (FET), across a Y2 cross-section, according to an embodiment.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components.

Reference will now be made in detail to the embodiments of the present invention, examples of which are illustrated in the accompanying drawings, where like reference numerals refer to like elements throughout. Backside processing has become popular as the density of the integrated circuit (IC) chips have increased. One problem, however, during some of the fabrication of the backside processes can lead to removal/etching of needed spacer/insulator/dielectric layers. The removal/etching of these layers can lead to shorts. During the silicide process an unneeded/unwanted lateral etch of the surround layer can occur. In subsequent processes, an oxide loss can occur (such as during metallization) that can create shorts in certain areas. The present invention addresses this problem by providing a liner prior to the silicide process. In an embodiment, after the substrate removal during backside processing (after a contact trench RIE and placeholder removal), a protective liner is formed (where the liner is formed). The protective liner prevents the lateral etching of the backside interlayer dielectric (BILD) layer during pre-cleaning silicide step and the silicide step. The protective liners prevent the lateral etch of the BILD layer that would expose a bottom surface of the gate and which ultimately cause shorting of the nanosheet device.

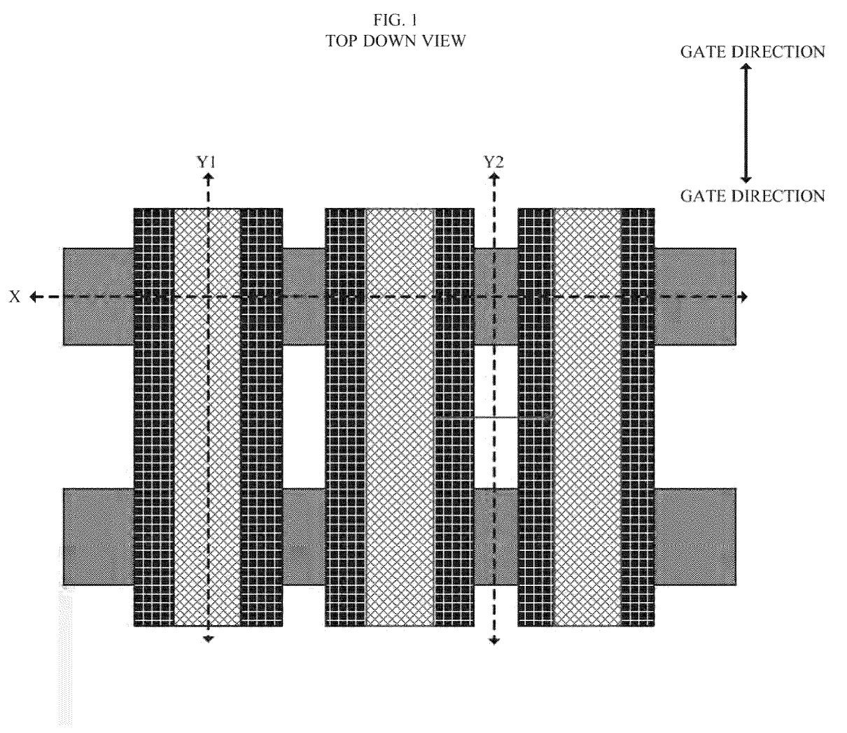

FIG. 1 illustrates a top-down view of multiple devices, in accordance with the embodiment of the present invention. The cross-section X extends horizontally through nanosheet transistors. Cross-section X is perpendicular to the gate direction and cross section Y1 and Y2 are perpendicular to cross section X. Cross section Y1 is through the gate region and cross-section Y2 is through the source/drain region spanning across multiple adjacent nanosheet transistors.

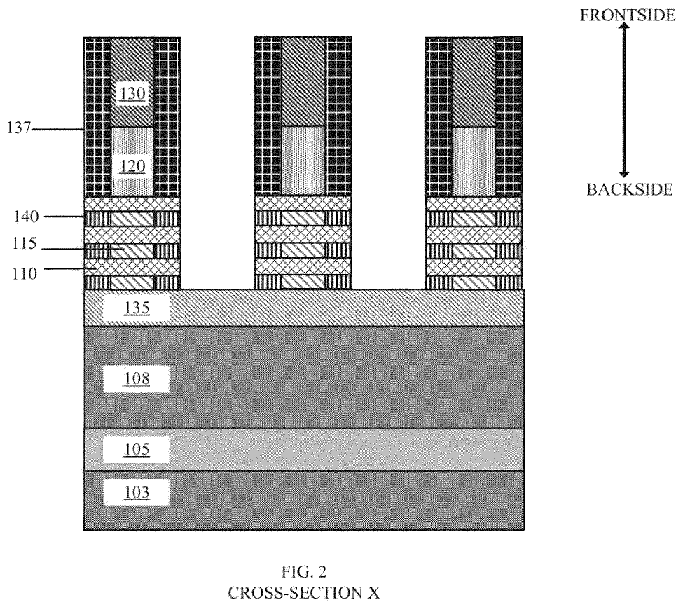

FIG. 2 shows a structure during an intermediate step of fabrication cut across the X cross-section as illustrated in FIG. 1. FIG. 2, illustrates a plurality of nano-stacks of a nanosheet transistor that includes a first substrate 103, an etch stop layer 105, a gate spacer 135, a plurality of alternating interleaving channel layers 110 and sacrificial layers 115, a dummy gate 120, a hardmask 130, and inner spacer layer 140.

The first substrate 103 and the second substrate 108 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the first substrate 103 and second substrate 108. In some embodiments, the first substrate 103 and the second substrate 108 may include semiconductor materials and dielectric materials. The first and second substrates 103 and 108 may also comprise an organic semiconductor or a layered semiconductor such as, for example, Si/SiGe, a silicon-on-insulator or a SiGe-on-insulator. A portion or the entire second semiconductor substrate 108 may also be comprised of an amorphous, polycrystalline, or monocrystalline. The second substrate 108 may be doped, undoped or contain doped regions and undoped regions therein.

The channel layers 110 and sacrificial layers 115 may form the channel regions. In FIG. 2, for ease of understanding, there are three alternating interleaving layers of channel layers 110 and sacrificial layers 115, to form three semiconductor layer pairs but more or less layers can be used in alternate embodiments depending on the number of channels desired. The plurality of channel layers 110 can be comprised of, for example, Si. The plurality of sacrificial layers 115, can be comprised of SiGe, where Ge is in percentage of 15 to 35 percent. Sacrificial layers 115 are recessed to create an empty space and filled with suitable material to form an inner spacer layer 140.

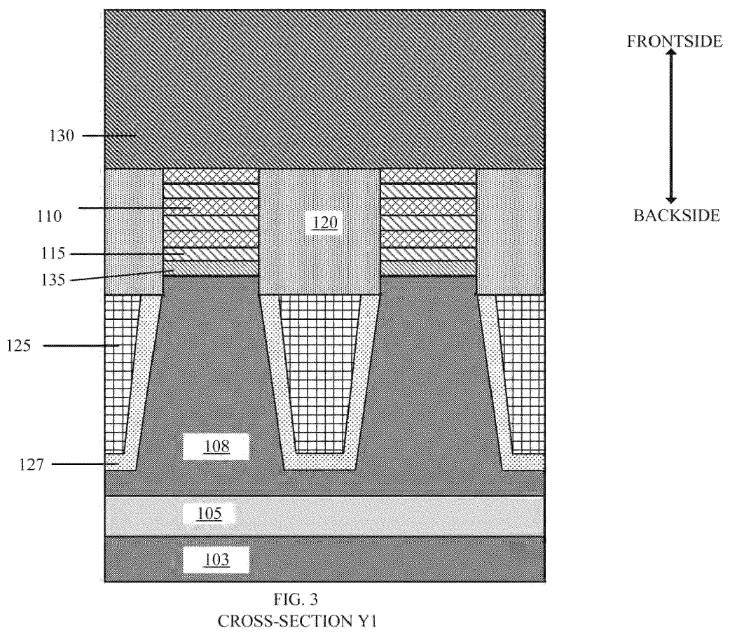

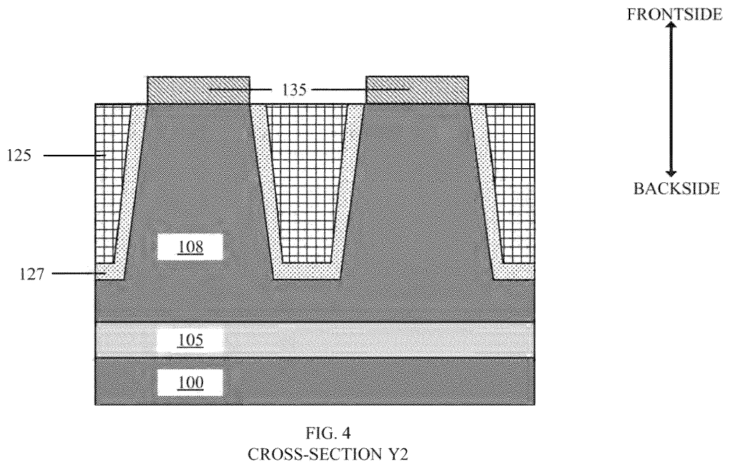

FIGS. 3 and 4 show the same process as FIG. 2 but from a Y1 and Y2 perspective, respectively. In FIG. 3, trenches (not shown) are formed in the second substrate 108 when separating the alternating layers to adjacent rows. FIG. 4 provides an alternate view perspective. These trenches (not shown) are filled with a liner 127 and a shallow trench isolation layer 125. The trenches (not shown) are used to form the source/drain regions.

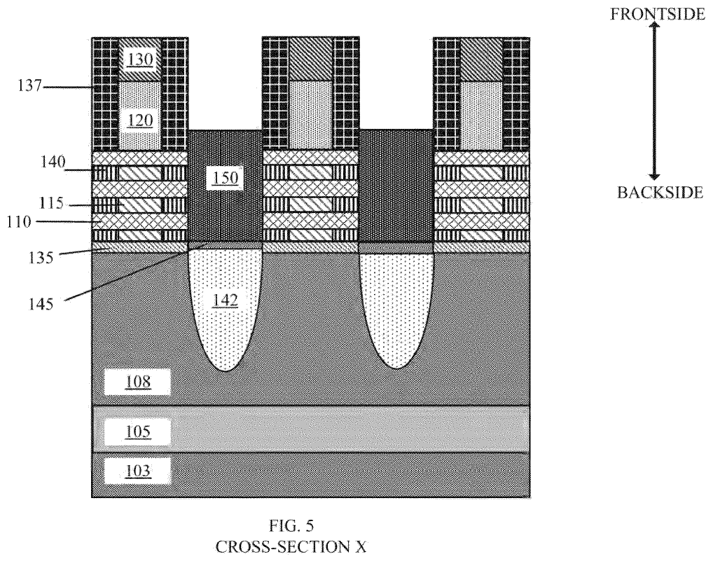

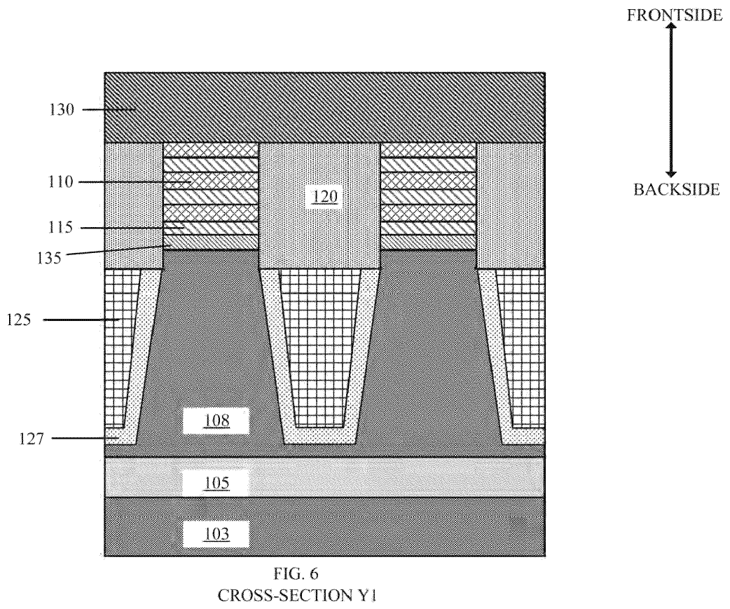

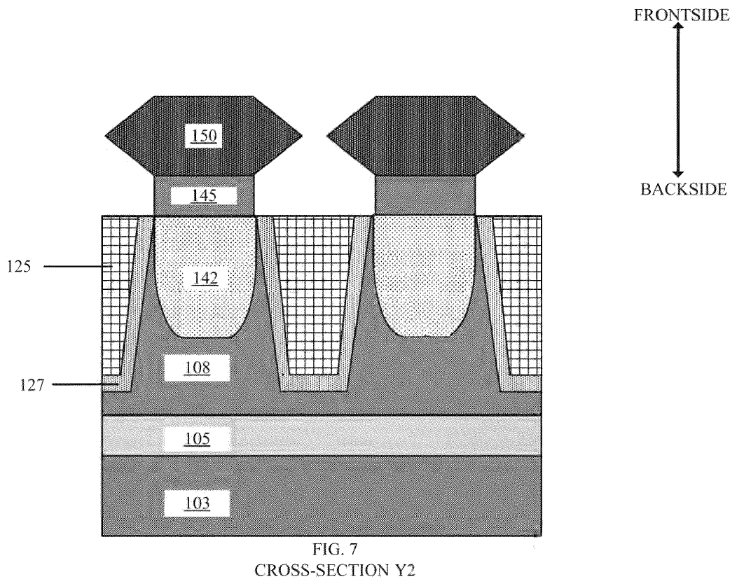

FIGS. 5-7 illustrate the next processing stage after formation of a placeholder 142 and a source/drain spacer 145. The source/drain spacer 145 acts as a separating layer between placeholder 142 and a source/drain 150. In forming the placeholder, trenches (not shown) are formed in the source/drain region and filled. The source/drain spacer 145 is formed on the frontside surface of the placeholder layers 142. The source/drain spacer 145 can be comprised of, for example, Si. The source/drains 150 are epitaxially grown above the source/drain spacer 145.

The source/drain 150 may be an n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

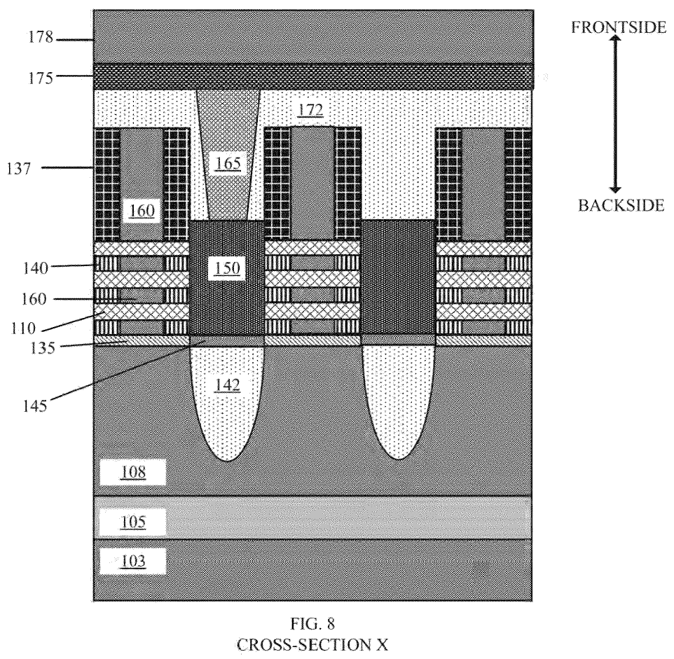

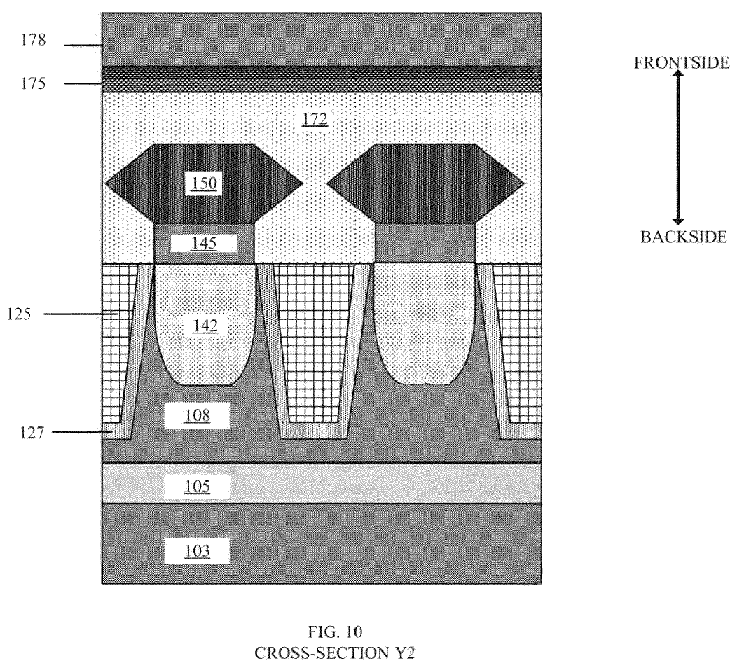

FIGS. 8-10 show the next processing stage from an X, Y1 and Y2 perspective, respectively. The dummy gate 120 and the hardmask 130 layers are removed and the sacrificial layers 115 are replaced to form the gate 160. Gate 160 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

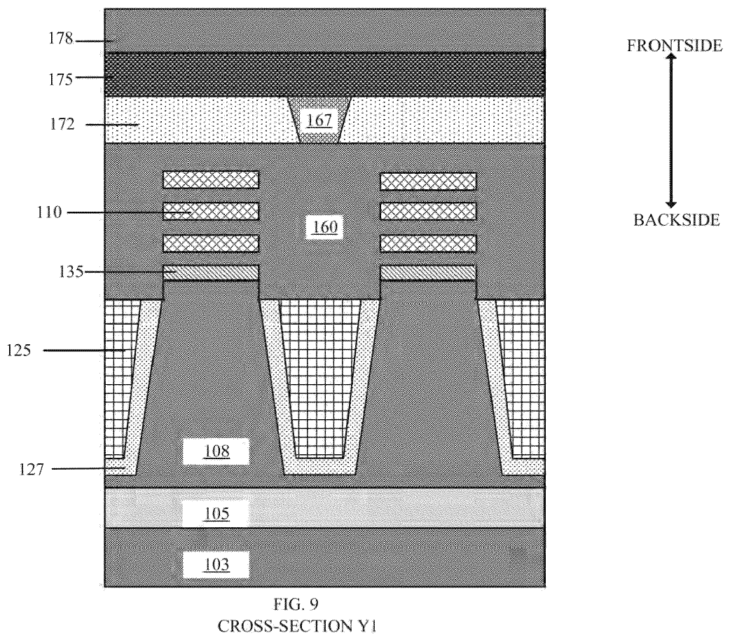

An interlayer dielectric 172 layer is formed to extend on top of the gate 160. Trenches (not shown) are formed to expose a frontside surface of a source/drain 150 and filled using a metallization process with a conductive metal, to form a frontside source/drain contact 165 (shown in FIG. 8) and a gate contact 167 (shown in FIG. 9). A back-of-the-line (BEOL) frontside interconnect 175 is formed above interlayer dielectric 172. The back-of-the line frontside interconnect 175 may be comprised of gate connections vias (not shown). The back-of-the-line frontside interconnect 175 may be comprised of multiple layers, metal lines, gate connection, skip vias and other components. A carrier wafer 178 is formed above the back-of-the line frontside interconnect 175. The carrier wafer 178 allows nanosheet device (i.e, the chip) to be flipped over for backside processing.

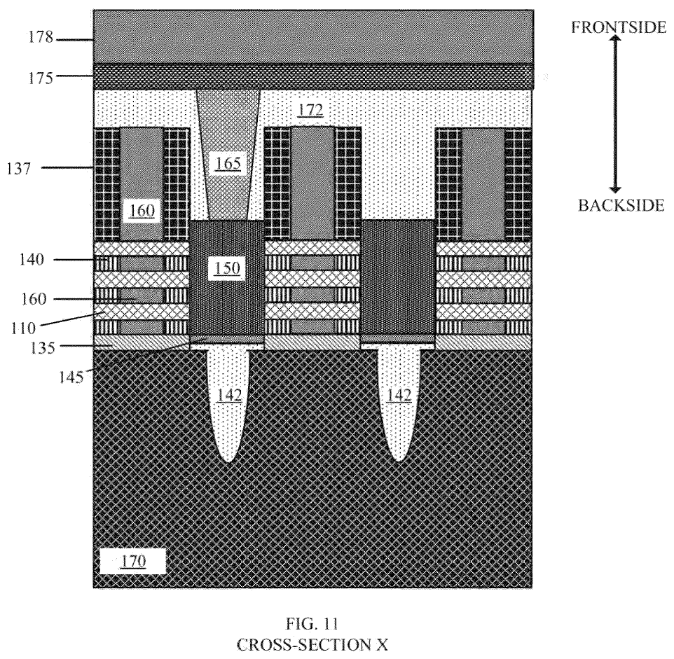

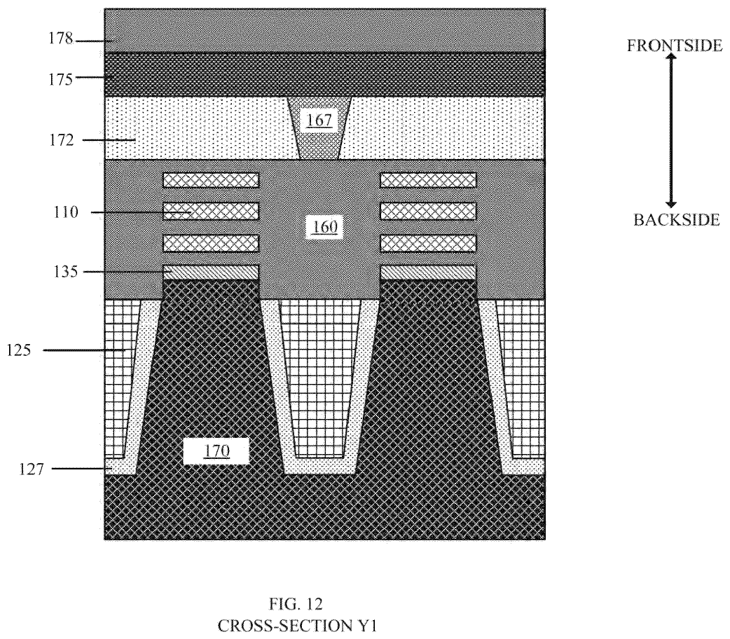

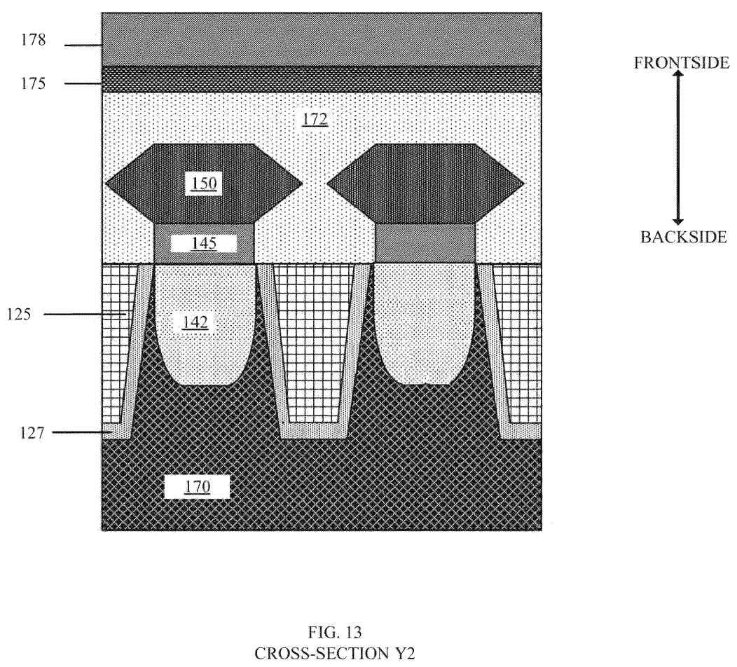

FIGS. 11-13, show the resulting structure after the nanosheet (device) is flipped upside down (not shown as flipped in the figures). However, for ease of viewing and understanding, the figures do not illustrate the flipping of the nanosheet field-effect-transistor (FET). The flipping allows accessibility to the backside for further processing of the backside elements.

The first substrate 103, the etch stop 105 and the second substrate 108 are removed. The placeholder layer 142 is thinned during the process to remove the second substrate 108. A backside interlayer dielectric (BILD) 170 is formed 108 on the backside surface of the gate spacer 135 and around the placeholder 142.

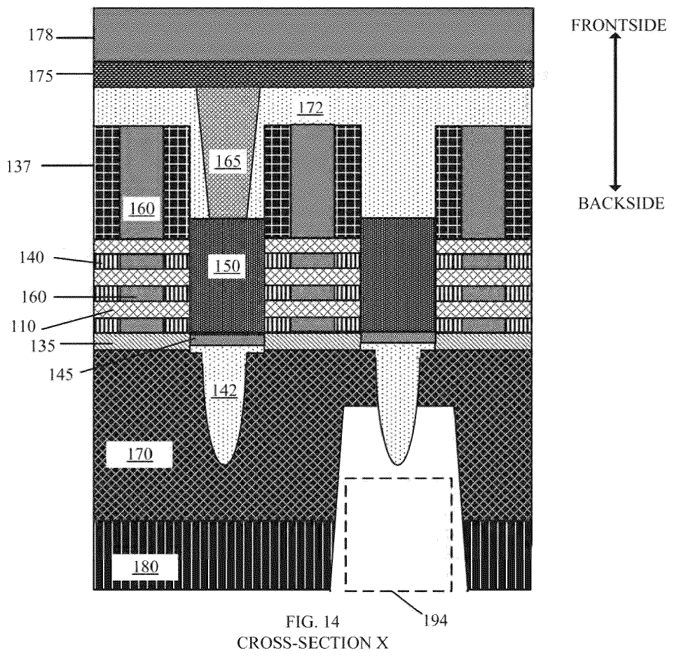

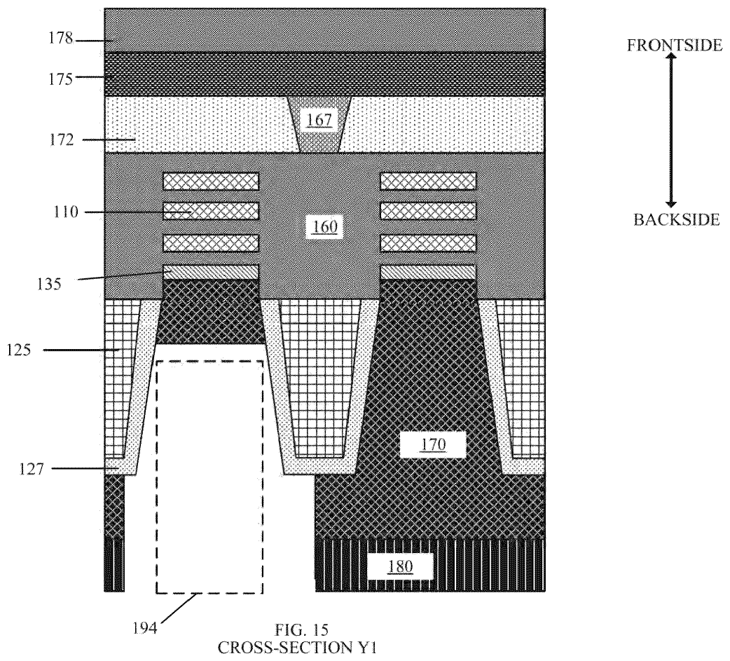

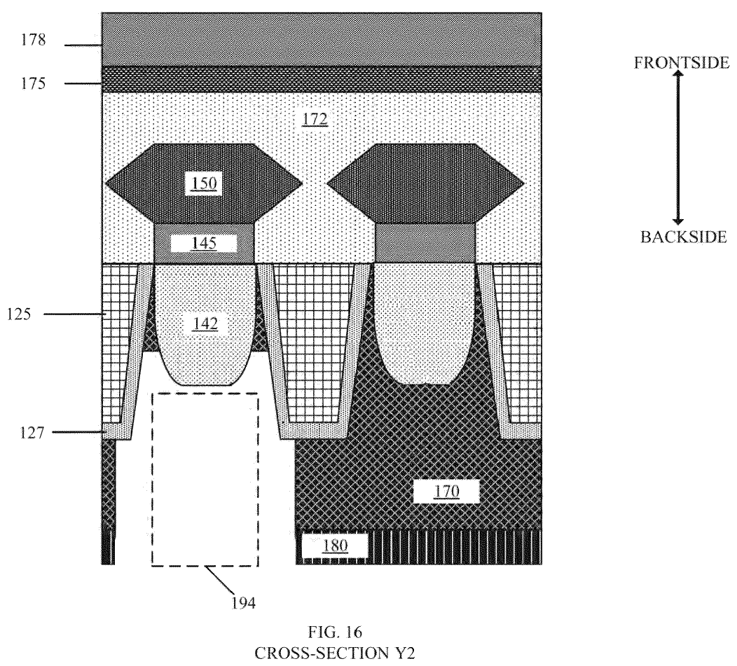

FIG. 14-16 show a processing stage after from an X, Y1 and Y2 perspective, respectively, where a lithography layer 180 is formed and patterned on top of the backside interlayer dielectric 170. The lithography layer 180 is used to selectively etch backside interlayer dielectric (BILD) 170 to form a backside contact trench in dash-line 194. The backside contact trench 194 exposes one of the placeholder 142 partially.

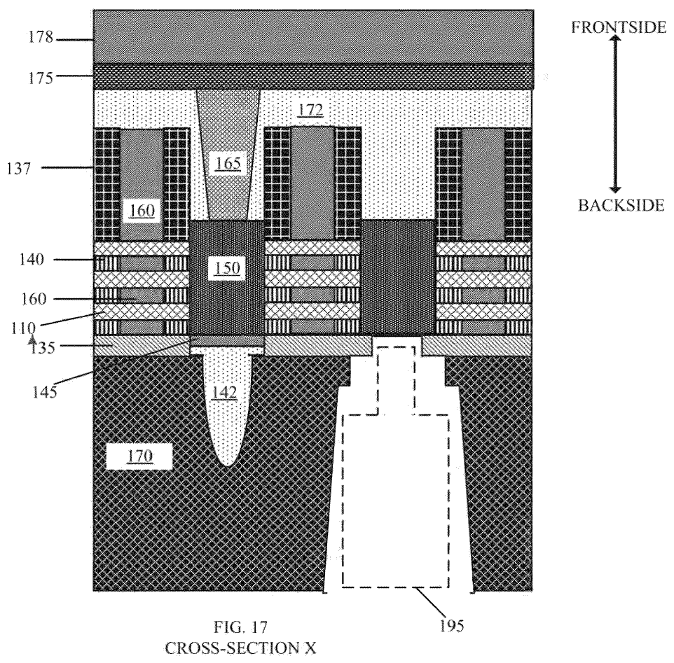

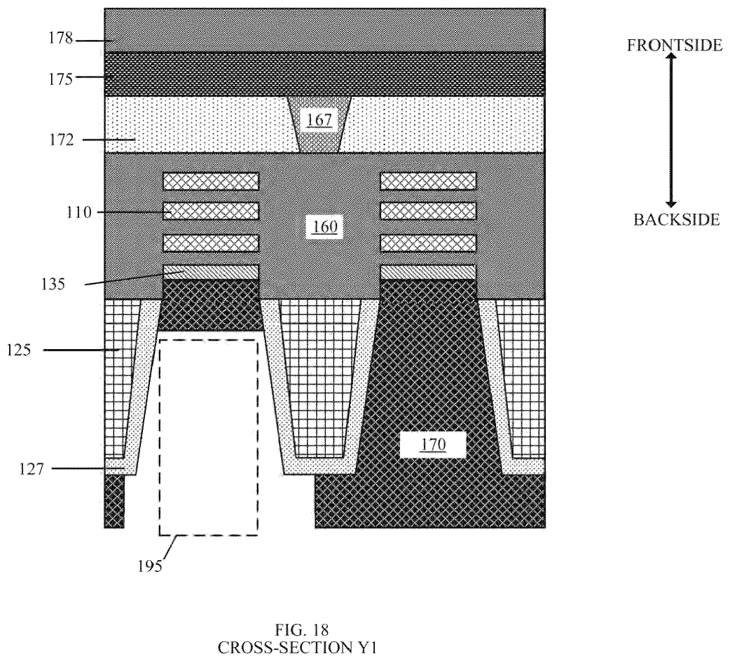

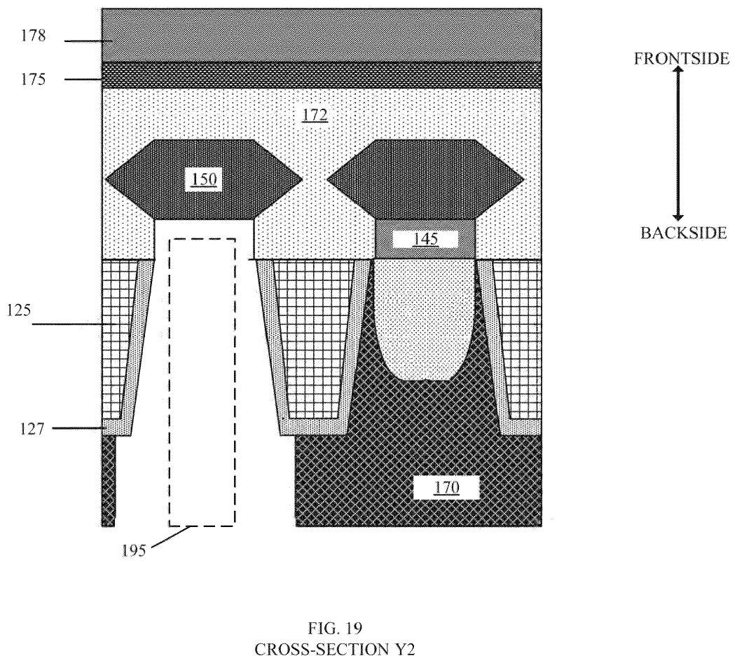

FIGS. 17-19 illustrate a processing stage after from an X, a Y1 and Y2 cross-section view, respectively, where the resulting structure shows the backside contact trench to have been expanded by removing the placeholder 142 and the source/drain spacer 145 to form an expanded backside contact trench 195. The expanded backside contact trench 195 exposes a backside surface of the source/drain 150.

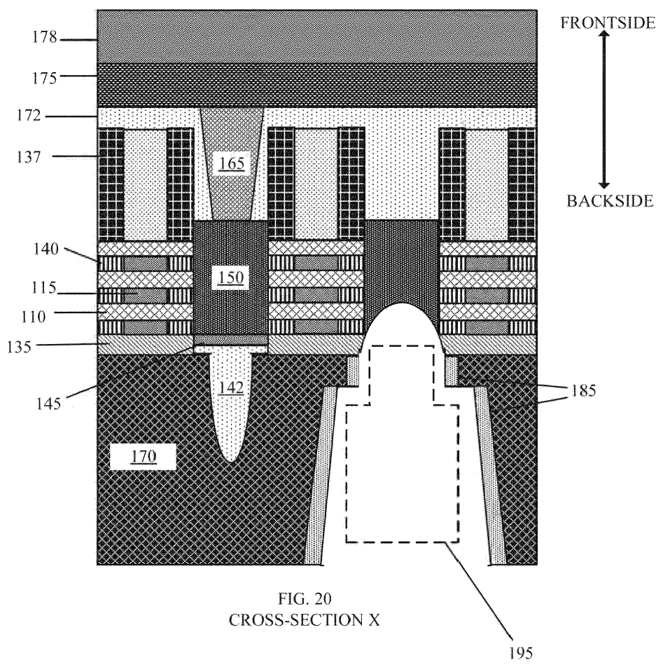

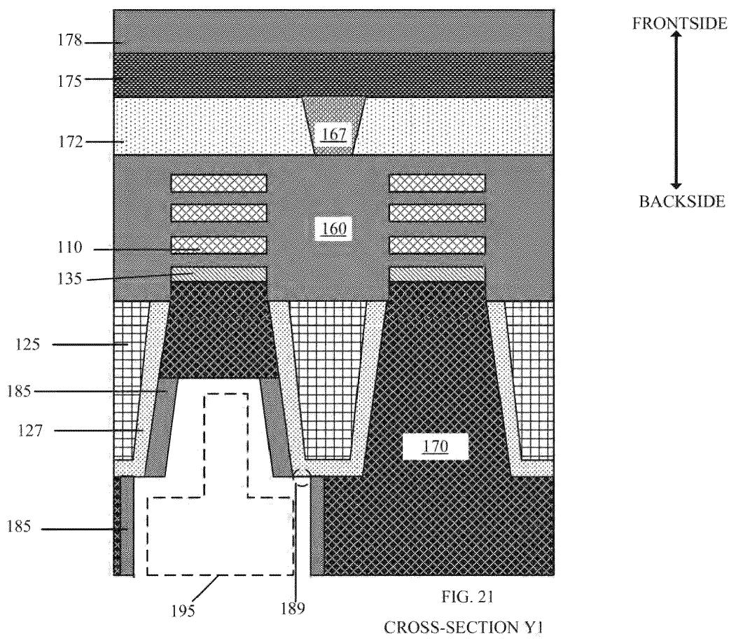

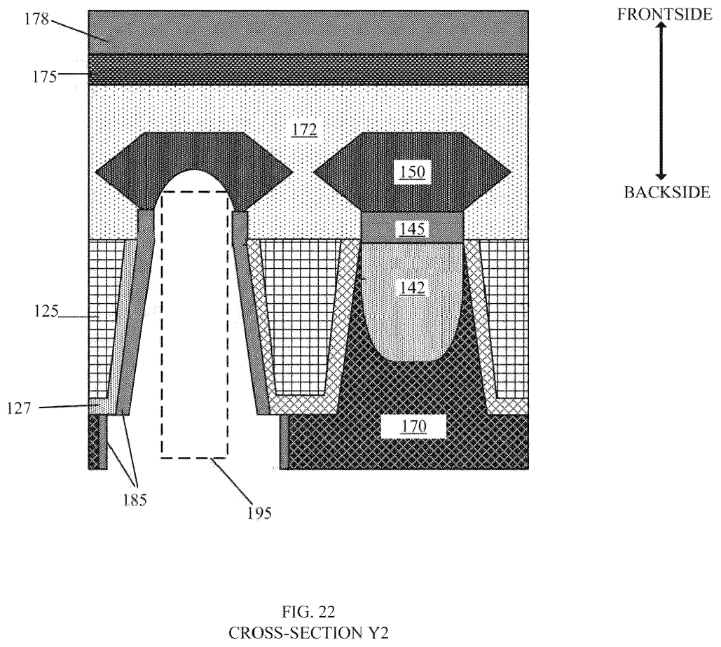

FIG. 20-22, illustrates a processing stage after the backside surface of the source/drain 150 is gouged to increase an exposed surface area. The vertical dielectric liner 185 is formed on the vertical sidewalls of the expanded contact trench 195. Portions of the vertical dielectric liner 185 are in contact with a backside surface of gate spacer 135 (see, for example, FIG. 20) and portions of the vertical dielectric liner 185 are in contact with a backside surface of the source/drain 150 (see, for example, FIG. 22). The vertical dielectric liner 185 that is formed on the vertical sidewalls of the expanded backside contact trench 195 is also adjacent to the BILD 170 and/or a processing stage after the liner 127 (see FIG. 21, for example). A portion of the liner 127 remains exposed after the formation of the vertical dielectric liner 185 as emphasized by dashed circle 189 (see FIG. 21, for example). The vertical dielectric liner 185 extends vertically to have a surface that is adjacent to, and in contact with a backside surface of the source/drain 150 (See FIG. 22, for example).

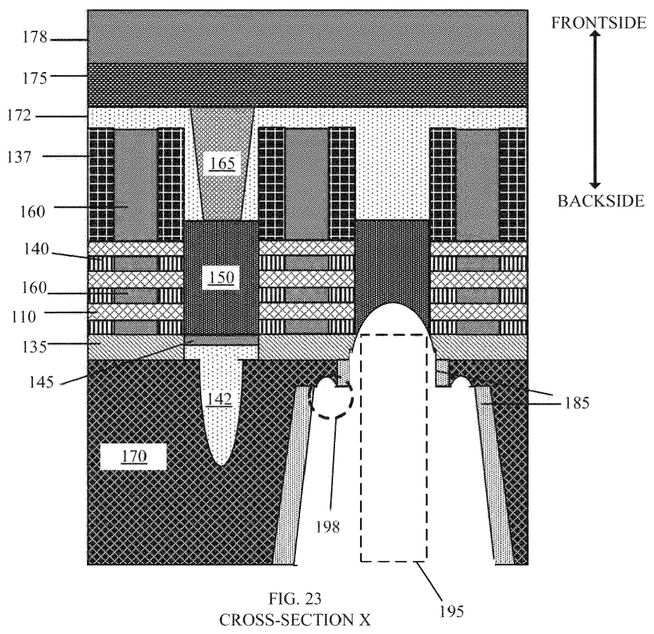

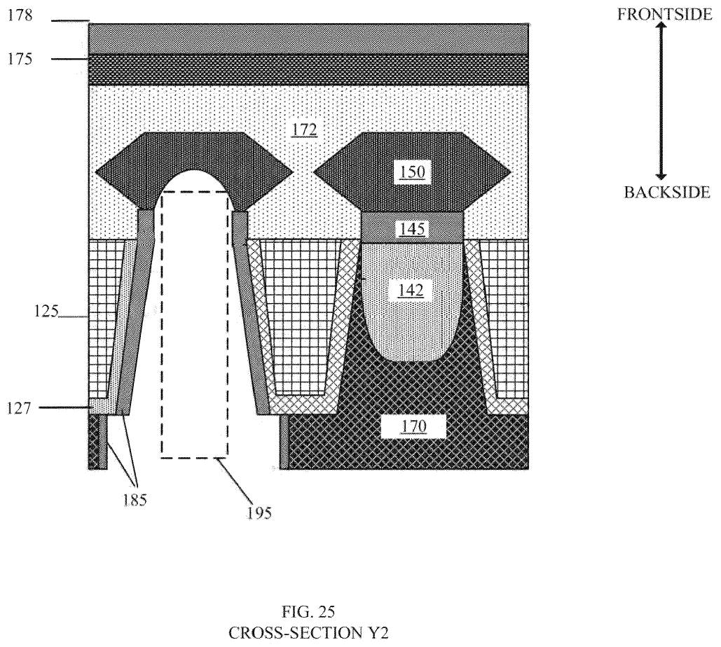

FIGS. 23, 24 and 25 a processing stage after a pre-silicide cleaning step has been performed, from an X, Y1 and Y2 cross-section perspective.

Typically, the pre-silicide cleaning steps causes the lateral etching of the backside interlayer dielectric layer that could lead to the exposure of a backside surface of the gate. The exposed backside surface of the gate can short to the backside contact.

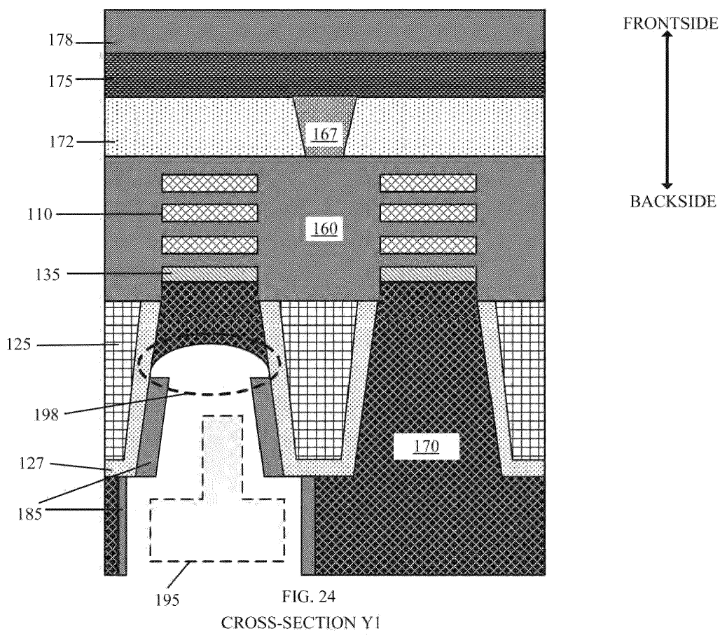

The present invention utilizes the vertical dielectric liner 185 to prevent the lateral etch from occurring during the pre-silicide cleaning step, thus preventing a backside surface of gate 160 from being exposed. Typically, portions of the backside interlayer dielectric may be removed during a pre-silicide cleaning and the vertical dielectric liner prevents the unintended removals. Therefore, areas covered by the vertical dielectric liner 185 and exposed, portions of the backside interlayer dielectric (170 is removed with it was exposed. The resulting structure provides an expanded backside contact trench 195 with a mushroom shape head 198 as can be viewed that exposes a frontside surface of the vertical dielectric liner 185, as emphasized in FIG. 24.

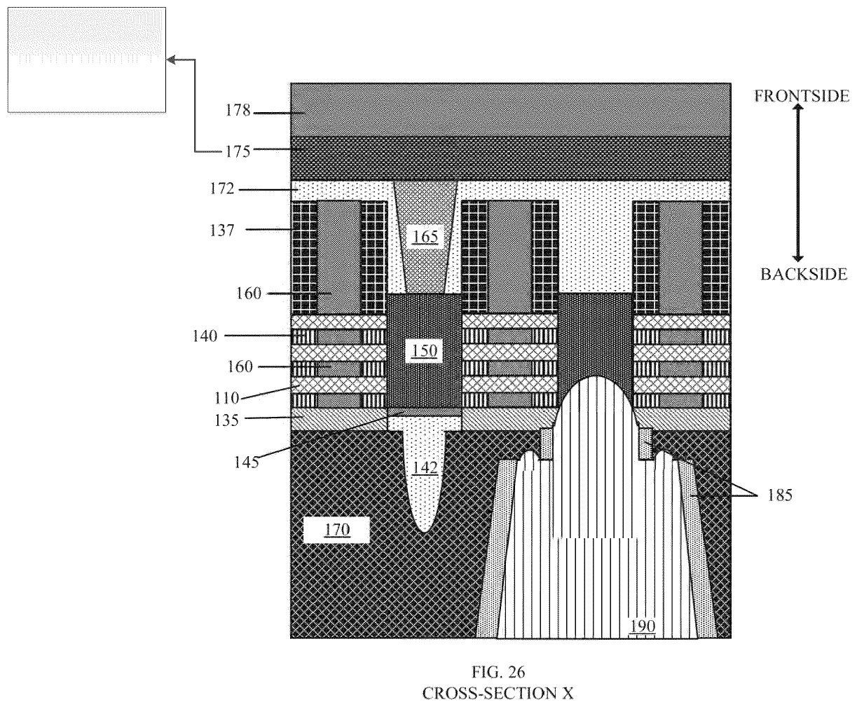

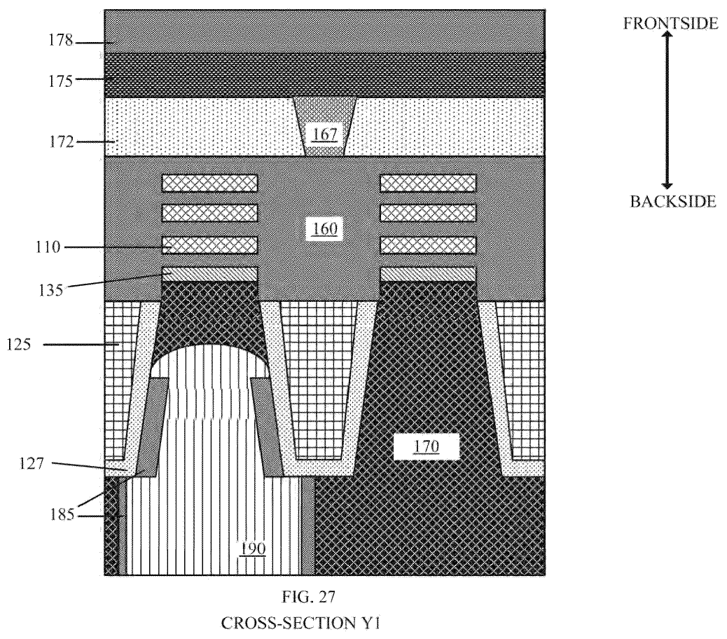

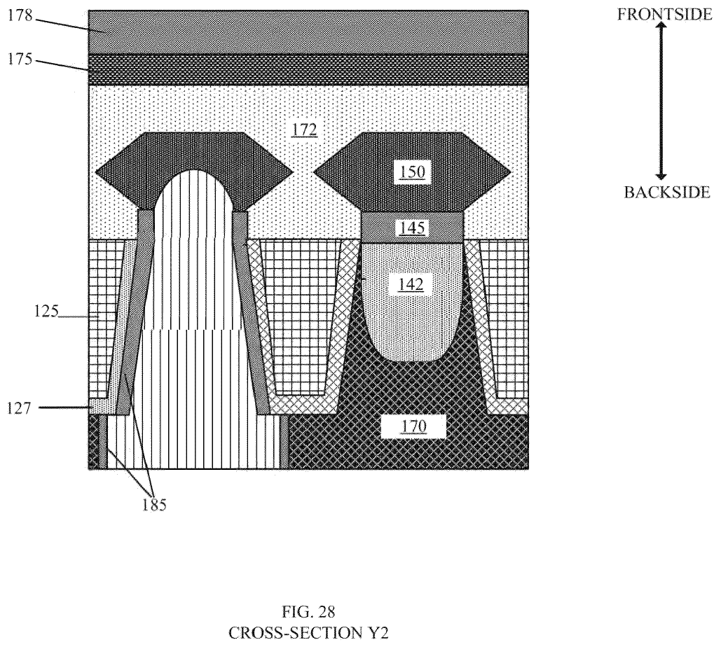

FIGS. 26-28 show a processing stage from an X, Y1 and Y2 cross-section perspective, respectively, after a metallization process is used to fill the expanded backside contact trench 195 with a conductive metal to form backside contact (BSCA) 190.

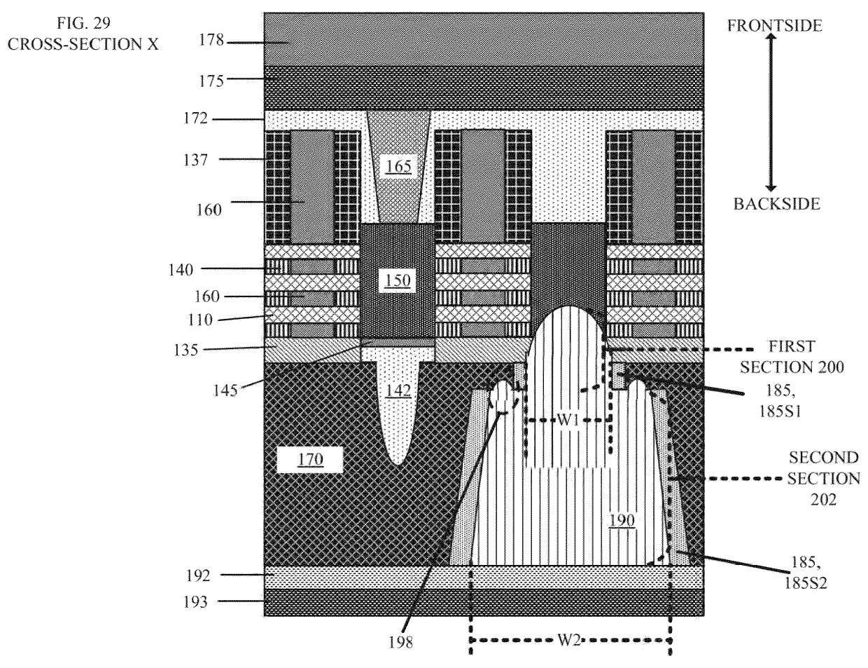

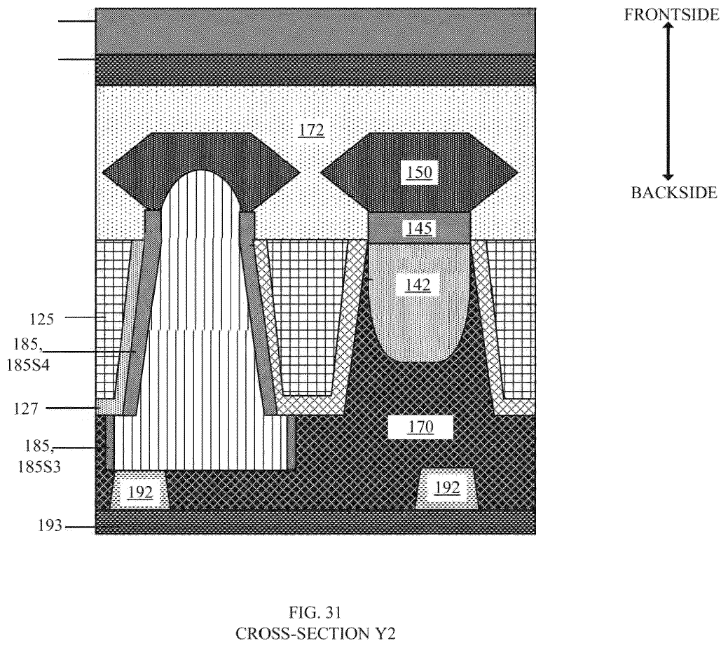

FIGS. 29-31 a processing stage resulting in a nanosheet field-effect-transistor (FET) from an X, Y1 and Y2 cross-section perspective. The resulting structure shows the backside contact 190 being in contact with source/drain 150.

The backside contact 190 includes a first section 200 and a second section 202. The dielectric liner 185 includes a plurality of segments for example 185S1, 185S2, 185S3, 185S4, that have been identified for simplicity reasons for describing the figures. The first section 200 has a first width W1 as measured perpendicular to the gate direction as illustrated in FIG. 29. The second section 202 has a second width W2 as measured perpendicular to the gate direction as illustrated in FIG. 29. The first width W1 has a value that is smaller than the value of the second width W2. The first section 200 of the backside contact 190 is adjacent to the vertical dielectric liner 185. The vertical dielectric liner segment 185S1, is located adjacent to a sidewall of this first section 200 of the backside contact 190.

The backside interlayer dielectric layer 170 is located adjacent to the vertical dielectric liner 185S2 and also adjacent to the second section 202 of the backside contact 190. The backside contact 190 is in contact with the backside interlayer dielectric layer 170 located the first segment 185S1 of the dielectric liner 185 and the second segment 185S2 of the dielectric liner 185. The backside interlayer dielectric layer 170 is located adjacent to the vertical dielectric liner 185S3, wherein the backside contact is in contact with the backside interlayer dielectric layer 170 between the two vertical segments of the plurality vertical segments of the dielectric liner (185S2 and 185S3).

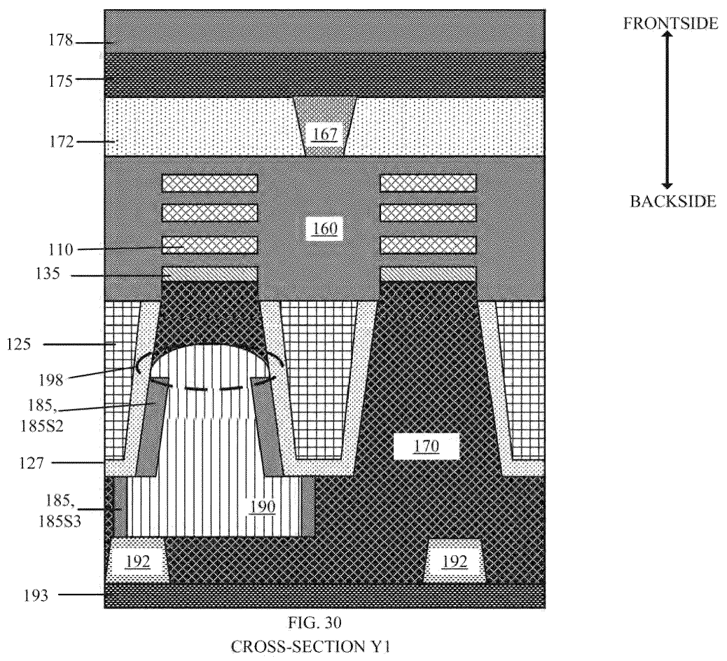

In an embodiment, when viewed from a Y1 cross-section perspective (parallel to the gate direction and through a gate region) as shown in FIG. 30, the backside contact 190 has a mushroom shape head 198 that overlaps the frontside surface of the second segment 185S2 of the dielectric liner 185 when viewed parallel to the gate direction through a gate region. The mushroom head 198 of the backside contact 190 appears as hill/bump/protrusion located between the first segment 185S1 of the dielectric liner 185 and the second segment 185S2 of the dielectric liner 185 as illustrated in FIG. 29.

As illustrated in FIG. 30, the backside contact 190 is in contact with a portion of the liner 127 located around a shallow trench isolation layer 125. More specifically the backside contact 190 is in contact with a portion of the liner 127 located between a the second segment 18582 and the third segment 185S3 of the dielectric liner 185.

A plurality of metal lines 192 are provided below the backside contact 170. The plurality of metal lines 192 can be, for example, power rails, such as VSS or VDD, single lines, ground lines, or any other type of connection lines. A backside interconnect 193 is located on the backside surface of the BILD 170, the backside contact 190, and the third segment 185S3 of the dielectric liner 185. The backside interconnect 193, can be for example, a backside-power-distribution-network, comprised of one more layers, metal lines, vias, skip vias, or a combination thereof.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure, comprising:
a nanosheet field-effect-transistor (FET) includes a source/drain;
a backside contact connected to a backside surface of the source/drain, wherein the backside contact has a first section having a first width as measured perpendicular to a gate direction, wherein the backside contact has a second section having a second width as measured perpendicular to the gate direction, and wherein the first width is smaller than the second width;
a vertical dielectric liner that includes a plurality of vertical segments, wherein each of the vertical segments of the vertical dielectric liner are located adjacent to a sidewall of a first section of the backside contact, and
a backside interlayer dielectric layer located adjacent to the vertical dielectric liner, wherein the backside contact is in contact with the backside interlayer dielectric layer between the two vertical segments of the plurality vertical segments of the dielectric liner.

2. The microelectronic structure of claim 1, wherein the backside contact has a mushroom shape head that when viewed parallel to the gate direction through a gate region.

3. The microelectronic structure of claim 2, wherein mushroom shape head of the backside contact overlaps a frontside surface of one of the vertical segments of the plurality of segment of the vertical dielectric liner.

4. The microelectronic structure of claim 2, wherein the mushroom shape head of the backside contact has the shape of the hill when view from perpendicular to the gate direction.

5. The microelectronic structure of claim 1, wherein the one of the plurality of vertical segments of the vertical dielectric liner contacts a liner located between the backside contact and a shallow trench isolation layer.

6. The microelectronic structure of claim 1, wherein the backside contact has an extended portion that extends beyond the frontside surface of the vertical dielectric liner and is adjacent to the source/drain.

7. The microelectronic structure of claim 1, wherein the backside contact has a protrusion the extends between two vertical segments of the plurality vertical segments of the dielectric liner as viewed parallel to the gate direction through a gate region.

8. The microelectronic structure of claim 7, wherein the protrusion of the backside contact is in contact with the backside interlayer dielectric layer.

9. The microelectronic structure of claim 1, further comprising:
a plurality of backside metal lines, wherein one of the plurality of backside metal lines is in contact the backside contact.

10. The microelectronic structure of claim 9, wherein one of the plurality of backside metal lines is in contact with one of the plurality of vertical segments of the vertical dielectric liner.

11. A microelectronic structure, comprising:
a nanosheet field-effect-transistor (FET) includes a source/drain;
a backside contact connected to a backside surface of the source/drain, wherein the backside contact has a first section having a first width as measured perpendicular to a gate direction, wherein the backside contact has a second section having a second width as measured perpendicular to the gate direction, and wherein the first width is smaller than the second width;
a vertical dielectric liner that includes a plurality of vertical segments, wherein each of the vertical segments of the vertical dielectric liner are located adjacent to a sidewall of a first section of the backside contact, and
a backside interlayer dielectric layer located adjacent to the vertical dielectric liner, wherein the backside contact is in contact with the backside interlayer dielectric layer between the two vertical segments of the plurality vertical segments of the dielectric liner;
a liner located around a shallow trench isolation layer, wherein the backside contact is in contact with the liner between the two vertical segments of the plurality vertical segments of the dielectric liner.

12. The microelectronic structure of claim 11, wherein the backside contact has a mushroom shape head that when viewed parallel to the gate direction through a gate region.

13. The microelectronic structure of claim 12, wherein mushroom shape head of the backside contact overlaps a frontside surface of one of the vertical segments of the plurality of segment of the vertical dielectric liner.

14. The microelectronic structure of claim 12, wherein the mushroom shape head of the backside contact has the shape of the hill when view from perpendicular to the gate direction.

15. The microelectronic structure of claim 11, wherein the backside contact has an extended portion that extends beyond the frontside surface of the vertical dielectric liner and is adjacent to the source/drain.

16. The microelectronic structure of claim 11, wherein the backside contact has a protrusion the extends between two vertical segments of the plurality vertical segments of the dielectric liner as viewed parallel to the gate direction through a gate region.

17. The microelectronic structure of claim 16, wherein the protrusion of the backside contact is in contact with the backside interlayer dielectric layer.

18. A method for fabricating a microelectronic structure, comprising:
forming a nanosheet field-effect-transistor (FET) includes a source/drain;
forming a backside contact connected to a backside surface of the source/drain, wherein the backside contact has a first section having a first width as measured perpendicular to a gate direction, wherein the backside contact has a second section having a second width as measured perpendicular to the gate direction, and wherein the first width is smaller than the second width;
forming a vertical dielectric liner that includes a plurality of vertical segments, wherein each of the vertical segments of the vertical dielectric liner are located adjacent to a sidewall of a first section of the backside contact, and
forming a backside interlayer dielectric layer located adjacent to the vertical dielectric liner, wherein the backside contact is in contact with the backside interlayer dielectric layer between the two vertical segments of the plurality vertical segments of the dielectric liner.

19. The method of claim 18, further comprising:
forming the backside contact to have a mushroom shape head that when viewed parallel to the gate direction through a gate region.

20. The method of claim 19, wherein the mushroom shape head of the backside contact is formed to overlap a frontside surface of one of the vertical segments of the plurality of segment of the vertical dielectric liner.
